(19) United States
(12) Patent Application Publication
(10) Pub. No.: US 2011/0312152 A1
(43) Pub. Date: Dec. 22, 2011

(54) Methods of Fabricating Integrated Circuit Devices Using Selective Etching Techniques that Account for Etching Distance Variations

(76) Inventors: Yoon-Hae Kim, Yongin-si (KR); Je-Don Kim, Seoul (KR); Young-Mook Oh, Hwaseong-si (KR)

(21) Appl. No.: 12/816,649

(22) Filed: Jun. 16, 2010

(51) Int. Cl. H01L 21/02

(52) U.S. Cl. 438/397; 257/E21.011

(57) ABSTRACT

Methods of fabricating integrated circuit devices include forming an integrated circuit capacitor on a substrate. This integrated circuit capacitor includes a lower capacitor electrode, a capacitor dielectric region on the lower capacitor electrode and an upper capacitor electrode on the capacitor dielectric region. The upper capacitor electrode has a smaller surface area relative to the lower capacitor electrode. An interlayer insulating layer is formed on the integrated circuit capacitor. This interlayer insulating layer is polished to have a planarized surface thereon that is spaced from an upper surface of the upper capacitor electrode by a first distance and spaced from an upper surface of the lower capacitor electrode by a second distance greater than the first distance. A step is performed to selectively etch first and second via holes of unequal size in the interlayer insulating layer to expose the upper surface of the lower capacitor electrode and the upper surface of the upper capacitor electrode, respectively. This etching step is performed using an etching process that concurrently etches portions of the interlayer insulating layer associated with the first via hole at a faster rate than portions of the interlayer insulating layer associated with the second via hole, which is larger than the first via hole.

### FIELD OF THE INVENTION

The present invention relates to methods of fabricating integrated circuit devices and, more particularly, to methods of forming contact via holes using selective etching techniques.

### BACKGROUND

Due to the recent trends of semiconductor devices toward higher capacity, faster operation speed and higher integration density while shrinking in size, new designs of the semiconductor devices are proposed and great advances in their manufacturing processes are attempted. Accordingly, a lower electrode, a dielectric film, and an upper electrode are sequentially disposed on an interlayer insulating film to form a capacitor. In the course of manufacturing a semiconductor device, the capacitor is electrically connected to multiple interconnections, which penetrate the interlayer dielectric film to then be formed into a via contacting the lower electrode and the upper electrode.

When a viahole penetrating the interlayer dielectric film and exposing the lower electrode and the upper electrode is formed, a distance between a top surface of the interlayer dielectric film and a top surface of the lower electrode is different from a distance between the top surface of the interlayer dielectric film and a top surface of the upper electrode. Because a depth of the viahole exposing the lower electrode is different from a depth of the viahole exposing the upper electrode, it is quite difficult to apply the same etching process in forming the viaholes in a stable manner.

### SUMMARY

Methods of fabricating integrated circuit devices according to embodiments of the invention include forming an integrated circuit capacitor on a substrate. This integrated circuit capacitor includes a lower capacitor electrode, a capacitor dielectric region on the lower capacitor electrode and an upper capacitor electrode on the capacitor dielectric region. The upper capacitor electrode has a smaller surface area relative to the lower capacitor electrode. These methods further include forming an interlayer insulating layer on the integrated circuit capacitor. This interlayer insulating layer is polished to have a planarized surface thereon that is spaced from an upper surface of the upper capacitor electrode by a first distance and spaced from an upper surface of the lower capacitor electrode by a second distance greater than the first distance. A step is then performed to selectively etch first and second via holes of unequal size in the interlayer insulating layer to expose the upper surface of the lower capacitor electrode and the upper surface of the upper capacitor electrode, respectively. This etching step is performed using an etching process that concurrently etches portions of the interlayer insulating layer associated with the first via hole at a faster rate than portions of the interlayer insulating layer associated with the second via hole, which is larger than the first via hole. The etching step may include selectively etching first and second via holes of unequal size in the interlayer insulating layer using a reverse reactive ion etching (RIE) process.

Additional embodiments of the invention include fabricating an integrated circuit device by forming a substrate having an electrically conductive wiring pattern therein extending adjacent a surface thereof. A first etch stop layer is formed on the surface of the substrate. This etch stop layer covers at least a portion of the wiring pattern. An integrated circuit capacitor is then formed on the etch stop layer. This capacitor includes a lower capacitor electrode, a capacitor dielectric region on the lower capacitor electrode and an upper capacitor electrode on the capacitor dielectric region. The capacitor is configured so that the upper capacitor electrode has a smaller surface area relative to the lower capacitor electrode.

These methods further include forming a second etch stop layer on an upper surface of the upper capacitor electrode. Thereafter, an interlayer insulating layer is formed on the integrated circuit capacitor. The interlayer insulating layer is polished using a technique such as chemical mechanical polishing (CMP) to have a planarized surface thereon. This upper surface is spaced from an upper surface of the second etch stop layer by a first distance and is spaced from an upper surface of the capacitor dielectric layer by a second distance greater than the first distance. The upper surface is also spaced from an upper surface of the first etch stop layer by a third distance greater than the second distance. First, second and third via holes of unequal size are then etched into the interlayer insulating layer. This etching step is performed using an etching process that exposes the second etch stop layer in the first via hole, the capacitor dielectric layer in the second via hole and the first etch stop layer in the third via hole at about the same time. To achieve this result, the first via hole is larger than the second via hole and the second via hole is larger than the third via hole. An etching process to achieve this result may be a reverse reactive ion etching (RIE) process.

### BRIEF DESCRIPTION OF THE DRAWINGS

FIG. 1 is a layout view of an intermediate structure illustrating a method of manufacturing a semiconductor device according to an exemplary embodiment of the present invention;

FIG. 2 is a cross-sectional view taken along the line II-II′ of FIG. 1;

FIG. 3 is a layout view of an intermediate structure illustrating a method of manufacturing a semiconductor device according to an exemplary embodiment of the present invention;

FIG. 4 is a cross-sectional view taken along the lines A-A′, B-B′, and C-C′ of FIG. 3;

FIG. 5 is a layout view of an intermediate structure illustrating a method of manufacturing a semiconductor device according to an exemplary embodiment of the present invention;

FIG. 6 is a cross-sectional view taken along the lines A-A′, B-B′, and C-C′ of FIG. 5;

FIGS. 7 and 8 are cross-sectional views illustrating a method of manufacturing a semiconductor device according to another exemplary embodiment of the present invention; and

FIGS. 9 through 11 are cross-sectional views of intermediate structures illustrating a method of manufacturing a semiconductor device according to still another exemplary embodiment of the present invention.

### DETAILED DESCRIPTION OF THE EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

Spatially relative terms, such as “below,” “beneath,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Like numbers refer to like elements throughout.

Exemplary embodiments of the invention are described herein with reference to cross-section illustrations that are schematic illustrations of idealized exemplary embodiments (and intermediate structures) of the present invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

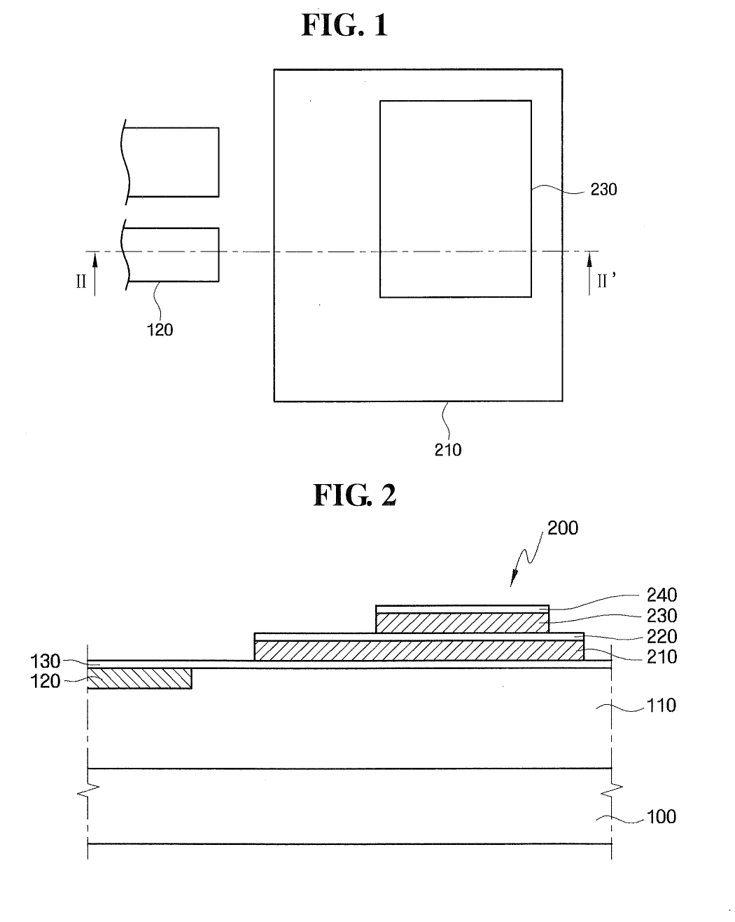

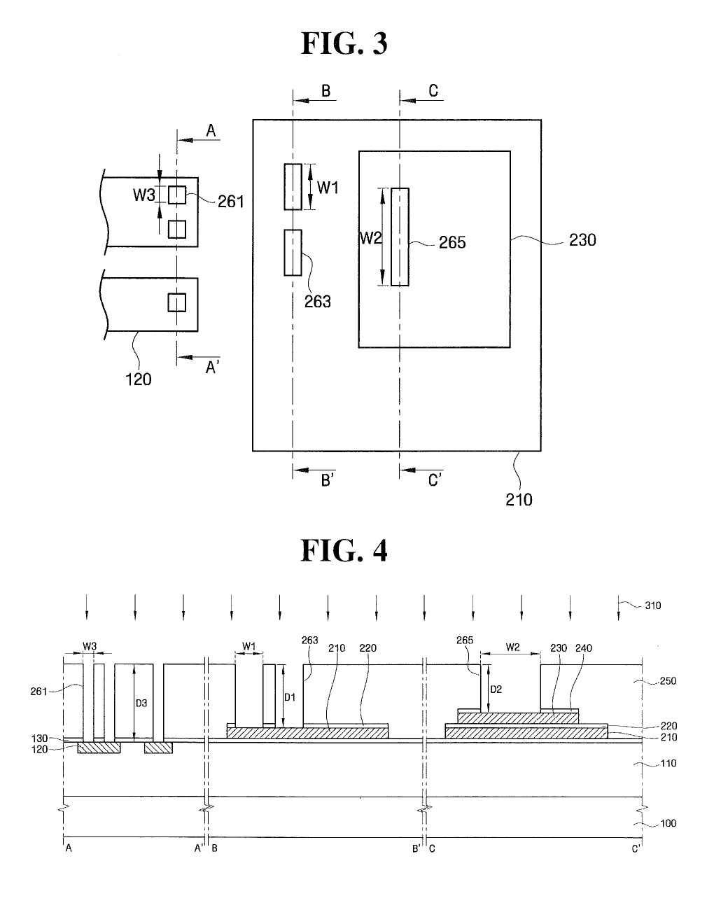

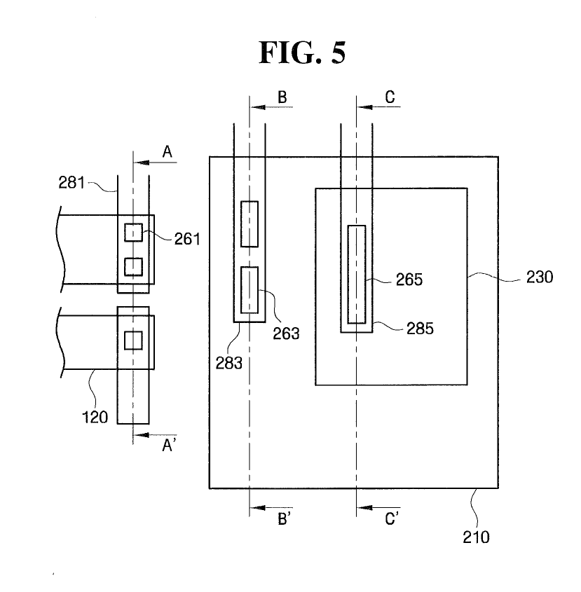

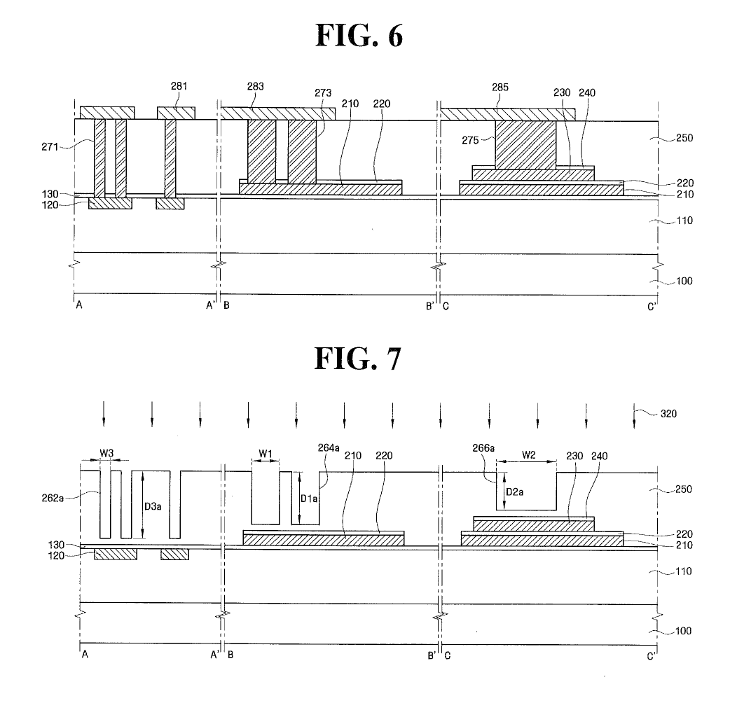

First, a method of manufacturing a semiconductor device according to an exemplary embodiment of the present invention will be described with reference to FIGS. 1 through 6. FIG. 1 is a layout view of an intermediate structure illustrating a method of manufacturing a semiconductor device according to an exemplary embodiment of the present invention, FIG. 2 is a cross-sectional view taken along the line II-II′ of FIG. 1, FIG. 3 is a layout view of an intermediate structure illustrating a method of manufacturing a semiconductor device according to an exemplary embodiment of the present invention, FIG. 4 is a cross-sectional view taken along the lines A-A′, B-B′, and C-C′ of FIG. 3, FIG. 5 is a layout view of an intermediate structure illustrating a method of manufacturing a semiconductor device according to an exemplary embodiment of the present invention, and FIG. 6 is a cross-sectional view taken along the lines A-A′, B-B′, and C-C′ of FIG. 5.

Referring to FIGS. 1 and 2, a first interlayer dielectric film 110 and a capacitor 200 are formed on a substrate 100. More concretely, the first interlayer dielectric film 110 including a lower interconnection 120 is formed on the substrate 100, the capacitor 200 including a first electrode 210, a dielectric film 220 and a second electrode 230 sequentially formed one after another, is formed on the first interlayer dielectric film 110.

Examples of the substrate 100 may include a silicon substrate, a silicon-on-insulator (SOI) substrate, a silicon germanium substrate, and the like. However, the exemplary substrates are provided only for illustrative purposes and another kind of substrate may be used according to use.

The first interlayer dielectric film 110 is formed on the substrate 100, including the lower interconnection 120. Here, the first interlayer dielectric film 110 may include, for example, a silicon oxide film, a silicon nitride film, a carbon-containing silicon oxide film (SiOₓC_{y}), a low dielectric organic film (CₓH_{y}), and so on.

The lower interconnection 120 may include, for example, copper (Cu), but not limited thereto.

The capacitor 200 is formed on the first interlayer dielectric film 110, including the first electrode 210, the dielectric film 220 and the second electrode 230. Here, a width of the first electrode 210 may be greater than that of the second electrode 230, suggesting that a surface area of the first electrode 210 formed on the first interlayer dielectric film 110 is larger than that of the second electrode 230, and a length of the first electrode 210 is greater than that of the second electrode 230 based on the sectional surface when the first electrode 210 and the second electrode 230 are cut in an arbitrary direction, as shown in FIG. 1.

For example, the capacitor 200 may be a Metal-Insulator-Metal (MIM) capacitor. Although the illustrated capacitor includes only the first electrode 210 and the second electrode 230, the capacitor may further include a third electrode (not shown) formed on the second etching stopper film 240 stacked on the second electrode 230. That is to say, a dual MIM capacitor may be used as the capacitor 200.

Here, the first and second electrodes 210 and 230 may be formed of a single layer or a combination layer made of at least one selected from the group consisting of, but not limited to, Ti, TiN, TiW, Ta, TaN, W, WN, Pt, Ir, Ru, Rh, Os, Pd, or Al. The first electrode 210 and the second electrode 230 may be made of the same material, but may be made of different materials, if necessary.

In addition, the dielectric film 220 may be formed of a single layer or a combination layer made of at least one selected from the group consisting of, but not limited to, SiO₂, SiₓN_{y}, SiON, SiₓC_{y}, SiₓO_{y}N_{z}, SiₓO_{y}C_{z}AlₓO_{y}, HfₓO_{y}, TaₓO_{y}, a high dielectric constant (high k) material, and so on. In addition, the second etching stopper film 240 may further be formed on the second electrode 230 of the capacitor 200.

Here, the second etching stopper film 240 may be formed of substantially the same material as the first etching stopper film 130.

Selectively, a first etching stopper film 130 may be formed on the first interlayer dielectric film 110. That is to say, the first etching stopper film 130 is formed on the first interlayer dielectric film 110 and the capacitor 200 is formed on the first etching stopper film 130. Here, the first etching stopper film 130 may include, but not limited thereto, a silicon oxide film, a silicon nitride film, and so on.

In addition, the second etching stopper film 240 may further be formed on the second electrode 230 of the capacitor 200.

Referring to FIGS. 3 and 4, a second interlayer dielectric film 250 is formed on the first interlayer dielectric film 110 so as to cover the capacitor 200, and a first viahole 263 and a second viahole 265 are simultaneously formed in the second interlayer dielectric film 250.

More concretely, the second interlayer dielectric film 250 is formed on the first interlayer dielectric film 110 including the capacitor 200 so as to cover the capacitor 200. Here, the second interlayer dielectric film 250 may be formed of substantially the same material as the first interlayer dielectric film 110. Here, in order to planarize a top surface by reducing a step height due to the existence of the capacitor 200, a chemical mechanical polishing (CMP) process may be performed on the second interlayer dielectric film 250.

Next, a first viahole 263 and a second viahole 265 are simultaneously formed, the first viahole 263 penetrating the second interlayer dielectric film 250, exposing the first electrode 210 and having a first width W1 and the second viahole 265 penetrating the second interlayer dielectric film 250, exposing the second electrode 230 and having a second width W2 greater than the first width W1.

Here, the simultaneously forming of the first viahole 263 and the second viahole 265 means forming the first viahole 263 and the second viahole 265 by a single process. That is to say, while removing the second interlayer dielectric film 250, an etching step for forming the first viahole 263 and the second viahole 265 is performed within a single process, e.g., within a single etching process.

However, the simultaneously forming of the first viahole 263 and the second viahole 265 is not limited to simultaneously exposing the first electrode 210 by the first viahole 263 and exposing the second electrode 230 by the second viahole 265. Although not shown, etching mask patterns (not shown) corresponding to the first viahole 263 and the second viahole 265 are formed on the second interlayer dielectric film 250, and the second interlayer dielectric film 250 exposed by the etching mask patterns is removed, thereby forming openings corresponding to the first viahole 263 and the second viahole 265, respectively, within the single etching process.

Further, a third viahole 261 penetrating the second interlayer dielectric film 250, exposing the lower interconnection 120 and having a third width W3 may also be formed when the first viahole 263 and the second viahole 265 are formed. That is to say, the first viahole 263, the second viahole 265 and the third viahole 261 may be simultaneously formed.

As shown in FIG. 3, the first width W1 of the first viahole 263 is greater than the third width W3 of the third viahole 261, the second width W2 of the second viahole 265 is greater than the first width W1 of the first viahole 263. That is to say, the following relationship between the first width W1 of the first viahole 263, the second width W2 of the second viahole 265 and the third width W3 of the third viahole 261 may be satisfied:

W3<W1<W2.

The first through third viaholes 263, 265 and 261 may be oblong or rectangular shaped. That is to say, the first viahole 263 and the second viahole 265 may be shaped in the form of a rectangle two sides of which are longer than the other two. The widths W1 and W2 of the first viahole 263 and the second viahole 265 may mean longer sides, respectively.

Meanwhile, as shown in FIG. 4, a first depth D1 of the first viahole 263 is longer than a second D2 of the second viahole 265, and a third depth D3 of the third viahole 261 is longer than the first depth D1 of the first viahole 263. That is to say, the longer the first through third widths W1, W2 and W3 of the first through third viaholes 263, 265 and 261, the smaller the depths D1, D2 and D3 of the first through third viaholes 263, 265 and 261. That is to say, simultaneously forming of the first through third viaholes 263, 265 and 261 includes patterning the second interlayer dielectric film 250 by reverse reactive ion etching (RIE) process.

The reverse RIE process 310 may be a process corresponding to a general RIE process. In more detail, when a general RIE process is defined as a process in which an etch rate of a viahole is proportional to a width of the viahole, the reverse RIE process 310 can be defined as a process in which an etch rate of a viahole is inversely proportional to a width of the viahole. Here, the etch rate of a viahole means a speed at which a depth of the viahole is increased by patterning the second interlayer dielectric film 250.

The reverse RIE process 310 may be implemented by performing an etching process under different processing conditions from those of the RIE process. For example, the reverse RIE process 310 may be performed using 400 sccm Ar gas, 50 sccm CH₃F gas, and 3 sccm O₂ gas, which is, however, provided only for illustration. The reverse RIE process 310 may be implemented using various gases other than the illustrated gases.

As described above, if the second interlayer dielectric film 250 is patterned by the reverse RIE process 310, the first viahole 263 is etched more rapidly than the second viahole 265 because the first width W1 of the first viahole 263 is smaller than the second width W2 of the second viahole 265. Here, the etch rate of the first viahole 263 or the second viahole 265 means a speed at which the second interlayer dielectric film 250 is removed by an etching process, e.g., the reverse RIE process 310.

This may also mean that the first viahole 263 is formed to a depth greater than that of the second viahole 265 after patterning the second interlayer dielectric film 250 by the reverse RIE process 310, suggesting that a depth of the first viahole 263 is increased more rapidly than that of the second viahole 265 is.

Likewise, since the third width W3 of the third viahole 261 is smaller than the first width W1 of the first viahole 263, the third viahole 261 is etched more rapidly than the first viahole 263. In other words, the third viahole 261 is formed by the reverse RIE process 310 to a depth greater than that of the first viahole 263, suggesting that a speed at which a depth of the third viahole 261 is increased is greater than that at which a depth of the first viahole 263 is increased.

For example, the respective viaholes 261, 263 and 265 having different depths and widths W1, W2 and W3 inversely proportional to the depths of the respective viaholes 261, 263 and 265 can be formed by the reverse RIE process 310. As described above, when the second interlayer dielectric film 250 is patterned, while the first viahole 263 and the second viahole 265 may be formed so as to have different widths. In this case, a width of one of the first viahole 263, which is to be deepened more than the other, may be made to be greater than that of the other. That is to say, the first through third viaholes 261, 263 and 265 can be formed by adjusting processing conditions of the reverse RIE process 310 and the widths of the first through third viaholes 261, 263 and 265.

Referring to FIGS. 5 and 6, the first through third viaholes 263, 265 and 261 (FIG. 4) are filled, thereby forming first through third vias 271, 273 and 275, and first through third upper interconnections 281, 283 and 285 connected to the first through third vias 271, 273 and 275.

In more detail, the first through third viaholes 261, 263 and 265 are filled with a conductive material, e.g., Cu, thereby forming the respective vias 271, 273 and 275. Next, first through third upper interconnections 281, 283 and 285 contacting the first through third vias 271, 273 and 275 are formed.

Although not shown, an upper interconnection layer (not shown) containing, e.g., a conductive material, is formed on the second interlayer dielectric film 250 having the first through third vias 271, 273 and 275, a mask pattern is formed on the upper interconnection layer, the upper interconnection layer may be patterned to form the first through third upper interconnections 281, 283 and 285 using the mask pattern. Since shapes of the illustrated first through third upper interconnections 281, 283 and 285 are provided only for illustration, the first through third upper interconnections 281, 283 and 285 may be embodied in various forms.

In the method according to the first embodiment, viaholes are formed by adjusting depths of the respective viaholes, thereby minimizing the lower interconnection or electrode while forming the viaholes and preventing a punch-through phenomenon. In addition, since the viaholes having depths inversely proportional to width thereof by the reverse RIE process in a stable manner, the semiconductor device having improved reliability can be manufactured.

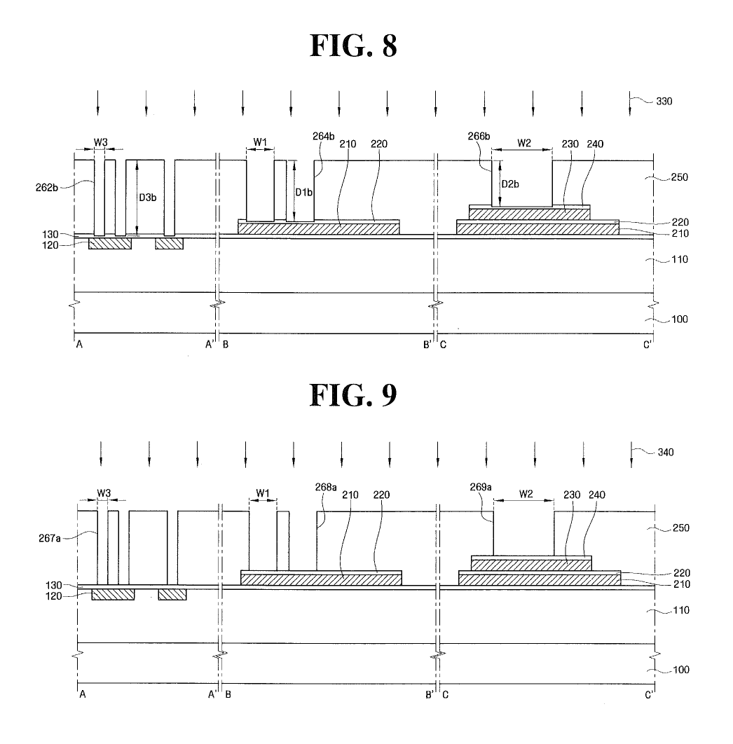

Hereinafter, a method for manufacturing a semiconductor device according to a second exemplary embodiment of the present invention will be described with reference to FIGS. 7 and 8. FIGS. 7 and 8 are cross-sectional views illustrating a method for manufacturing a semiconductor device according to a second exemplary embodiment of the present invention. For brevity, components each having the same function for describing the first embodiment are respectively identified by the same reference numerals, and their repetitive description will not be given or simplified.

The method according to the second exemplary embodiment of the present invention is different from that according the first exemplary embodiment in that first through third viaholes are formed by sequentially performing first and second etching processes.

Referring to FIG. 7, a first pre-viahole 264a and a second pre-viahole 266a partially penetrating the second interlayer dielectric film 250 by a first etching process 320. The first etching process 320 is a reverse RIE process, in which the first and second pre-viaholes 264a and 266a can be formed at an etch rate inversely proportional to widths of the first and second pre-viaholes 264a and 266a.

As described above, the first pre-viahole 264a having a first width W1 and the second pre-viahole 266a having a second width W2 greater than the first width W1, are formed by the reverse RIE process 320. Then, even if the reverse RIE process 320 is performed for the same period of time, a first depth D1a of the first pre-viahole 264a is greater than a second depth D2a of the second pre-viahole 266a, suggesting that the greater the width of a pre-viahole, the smaller the depth of the pre-viahole.

As shown in FIG. 7, the first pre-viahole 264a partially penetrates the second interlayer dielectric film 250 without exposing a dielectric film 220. The second pre-viahole 266a partially penetrates the second interlayer dielectric film 250 without exposing a second etching stopper film 240.

Next, referring to FIG. 8, a second etching process 330 is performed, thereby enlarging the first pre-viahole 264b and the second pre-viahole 266b, the first pre-viahole 264b penetrating the second interlayer dielectric film 250 and partially removing the dielectric film 220, and the second pre-viahole 266b penetrating the second interlayer dielectric film 250 and partially removing the second interlayer dielectric film 250.

Here, the second etching process 330 is a reactive ion etching (RIE) process, in which the first and second pre-viaholes 264b and 266b are enlarged at etch rates proportional to widths of the first and second pre-viaholes 264b and 266b. That is to say, the second pre-viahole 266b having a relatively greater width may be etched more rapidly than the first pre-viahole 264b having a smaller width.

Further, the third pre-viahole 262b may be subjected to substantially the same process with the first and second pre-viaholes 264b and 266b. That is to say, the first etching process 320 is performed to form the third pre-viahole 262a partially penetrating the second interlayer dielectric film 250, and the second etching process 330 is performed to increase the third pre-viahole 262b penetrating the second interlayer dielectric film 250 and partially removing a lower interconnection 120.

Although not shown, formation of the first through third viaholes can also be achieved by forming and enlarging the first through third pre-viaholes 262a, 264a and 266a. As described above in the first embodiment, the first through third vias can be formed by filling the first through third viaholes using a conductive material, for example, copper (Cu). According to the present invention, first through third upper interconnections contacting the first through third vias can also be formed.

In the method according to the second embodiment, the reverse RIE process and the RIE process are both viaholes are performed, preventing the first through third viaholes from completely exposing one of the lower interconnection, the first electrode and the second electrode due to a difference in the etch rate. In other words, the reverse RIE process and the RIE process are performed together, thereby allowing the first through third vias to contact the lower interconnection, the first electrode and the second electrode in a stable manner. Therefore, it is possible to prevent a punch-through phenomenon due to a difference between heights of the first through third vias, thereby manufacturing the semiconductor device having improved reliability.

Hereinafter, a method for manufacturing a semiconductor device according to a third exemplary embodiment of the present invention will be described with reference to FIGS. FIGS. 9 through 11. FIGS. 9 through 11 are cross-sectional views of intermediate structures illustrating a method for manufacturing a semiconductor device according to a third exemplary embodiment of the present invention. For brevity, components each having the same function for describing the first embodiment are respectively identified by the same reference numerals, and their repetitive description will not be given or simplified.

Referring to FIG. 9, a first etching process 340 is performed, thereby forming a first pre-viahole 268a and a second pre-viahole 269a, the first pre-viahole 268a exposing a dielectric film 220, and the second pre-viahole 269a exposing a second etching stopper film 240. Here, the first etching process 340 is a reactive ion etching (RIE) process. In addition, the first and second pre-viaholes 264a and 266a shown in FIG. 9 are the same as the first and second pre-viaholes 264a and 266a shown in FIG. 7 and designated by the same terms in that they are intermediated structures produced before forming first and second viaholes. However, the first and second pre-viaholes 268a and 269a shown in FIG. 9 are different from those shown in FIG. 7 in that they expose a dielectric film 220 by the first etching process 340.

For example, the first pre-viahole 268a having a first width W1 and the second pre-viahole 269a having a second width W2 greater than the first width W1 are formed by a reverse RIE process. Here, the first pre-viahole 268a exposes the dielectric film 220, and the second pre-viahole 269a exposes a second etching stopper film 240. In addition, a third pre-viahole 267a having a third width W3 smaller than the first width W1 may also be formed by the reverse RIE process, together with the first pre-viahole 268a and the second pre-viahole 269a.

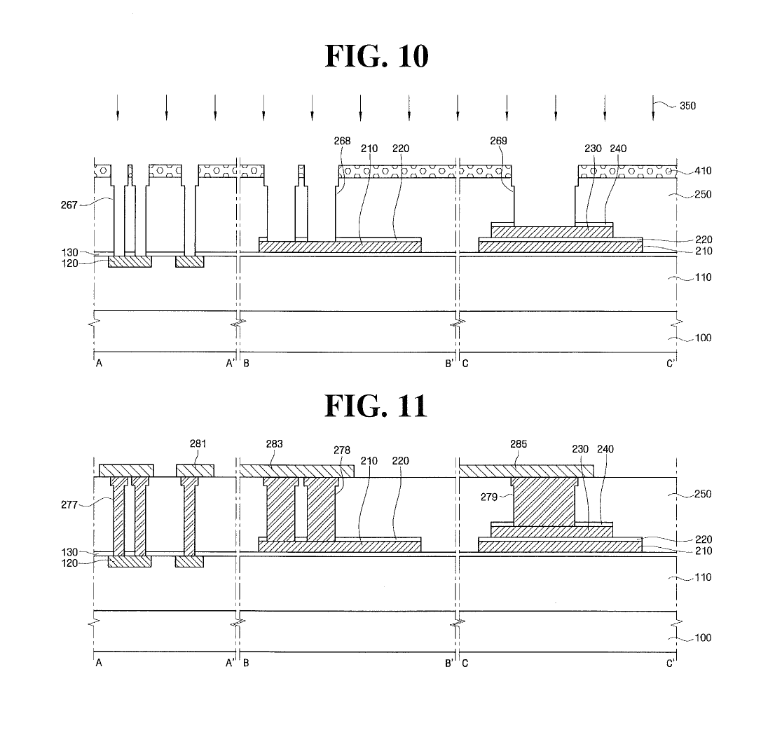

Referring to FIG. 10, a first viahole 268 and a second viahole 269 are formed by removing the dielectric film 220 exposed by the second etching process 350 and removing the second etching stopper film 240. The first viahole 268 exposes a first electrode 210, and the second viahole 269 exposes a second electrode 230. Here, the second etching process is a reactive ion etching (RIE) process. While the second etching process 350 is performed, a first trench hole having a width greater than the first width W1 is formed over the first viahole 268, and a second trench hole having a width greater than the second width W2 is formed over the second viahole 269.

In more detail, a mask pattern 410 is formed on the second interlayer dielectric film 250 having the first through third pre-viaholes (267a, 268a and 269a of FIG. 9), the mask pattern 410 having openings corresponding to first through third trench holes having widths greater than the widths W1, W2 and W3 of the first through third viaholes 267, 268 and 269. The first through third trench holes are formed over the first through third viaholes 267, 268 and 269 by performing a second etching process 350. At the same time, as shown in FIG. 9, the dielectric film 220 exposed by the first etching process 340, the second etching stopper film 240 and the first etching stopper film 130 are removed, thereby forming the first through third viaholes 267, 268 and 269 exposing the first electrode 210, the second electrode 230 and the lower interconnection 120, respectively.

Referring to FIG. 11, the first through third viaholes 267, 268 and 269 are filled with a conductive material, e.g., Cu, thereby forming the respective vias 277, 278 and 279. In addition, first through third upper interconnections 281, 283 and 285 are formed on the first through third vias 277, 278 and 279 to be electrically connected each other.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A method of fabricating an integrated circuit device, comprising:
forming an integrated circuit capacitor on a substrate, said integrated circuit capacitor comprising a lower capacitor electrode, a capacitor dielectric region on the lower capacitor electrode and an upper capacitor electrode on the capacitor dielectric region, said upper capacitor electrode having a smaller surface area relative to the lower capacitor electrode;
forming an interlayer insulating layer on the integrated circuit capacitor, said interlayer insulating layer having a planarized surface thereon that is spaced from an upper surface of the upper capacitor electrode by a first distance and spaced from an upper surface of the lower capacitor electrode by a second distance greater than the first distance; and
selectively etching first and second via holes of unequal size in the interlayer insulating layer to expose the upper surface of the lower capacitor electrode and the upper surface of the upper capacitor electrode, respectively, using an etching process that concurrently etches portions of the interlayer insulating layer associated with the first via hole at a faster rate than portions of the interlayer insulating layer associated with the second via hole, which is larger than the first via hole.

2. The method of claim 1, wherein said selectively etching comprises selectively etching first and second via holes of unequal size in the interlayer insulating layer using a reverse reactive ion etching (RIE) process.

3. The method of claim 1, wherein the substrate comprises an electrically conductive wiring pattern therein; wherein said selectively etching comprises selectively etching third, first and second via holes of unequal size in the interlayer insulating layer to expose an upper surface of the wiring pattern, the upper surface of the lower capacitor electrode and the upper surface of the upper capacitor electrode, respectively, using a reverse reactive ion etching (RIE) process.

4. The method of claim 1, wherein the substrate comprises an electrically conductive wiring pattern therein; wherein said selectively etching comprises selectively etching third, first and second via holes of unequal size in the interlayer insulating layer to expose an upper surface of the wiring pattern, the upper surface of the lower capacitor electrode and the upper surface of the upper capacitor electrode, respectively, using an etching process that concurrently etches portions of the interlayer insulating layer associated with the third via hole at a faster rate than portions of the interlayer insulating layer associated with the first via hole, which is larger than the third via hole.

5. The method of claim 1, wherein the substrate comprises an electrically conductive wiring pattern therein; wherein said forming an integrated circuit capacitor is preceded by forming a first etch stop layer on the wiring pattern; and wherein said selectively etching comprises selectively etching a third via hole through the interlayer insulating layer and the first etch stop layer to expose an upper surface of the wiring pattern.

6. A method of fabricating an integrated circuit device, comprising:
forming a substrate having an electrically conductive wiring pattern therein extending adjacent a surface thereof;
forming a first etch stop layer on the surface of the substrate, said etch stop layer covering at least a portion of the wiring pattern;
forming an integrated circuit capacitor on the etch stop layer, said integrated circuit capacitor comprising a lower capacitor electrode, a capacitor dielectric region on the lower capacitor electrode and an upper capacitor electrode on the capacitor dielectric region, said upper capacitor electrode having a smaller surface area relative to the lower capacitor electrode;
forming a second etch stop layer on an upper surface of the upper capacitor electrode;
forming an interlayer insulating layer on the integrated circuit capacitor, said interlayer insulating layer having a planarized surface thereon that is spaced from an upper surface of the second etch stop layer by a first distance and spaced from an upper surface of the capacitor dielectric layer by a second distance greater than the first distance and spaced from an upper surface of the first etch stop layer by a third distance greater than the second distance; and
selectively etching first, second and third via holes of unequal size in the interlayer insulating layer using an etching process that exposes the second etch stop layer in the first via hole, the capacitor dielectric layer in the second via hole and the first etch stop layer in the third via hole at about the same time;
wherein the first via hole is larger than the second via hole and the second via hole is larger than the third via hole.

7. The method of claim 6, wherein the etching process is a reverse reactive ion etching (RIE) process.

8. A method for manufacturing a semiconductor device, the method comprising:
forming a first interlayer dielectric film on a substrate, the first interlayer dielectric film including a lower interconnection;
forming a capacitor on the first interlayer dielectric film, the capacitor including a first electrode, a dielectric film and a second electrode sequentially formed one after another, a width of the first electrode being greater than that of the second electrode;
forming a second interlayer dielectric film on the first interlayer dielectric film so as to cover the capacitor; and
simultaneously forming a first viahole having a first width and a second viahole having a second width greater than the first width, the first and second viaholes penetrating the second interlayer dielectric film, the first viahole exposing the first electrode and the second viahole exposing the second electrode.

9. The method of claim 8, wherein the simultaneously forming of the first viahole and the second viahole comprises patterning the second interlayer dielectric film by a reverse reactive ion etching (RIE) process.

10. The method of claim 9, wherein the patterning of the second viahole comprises patterning the second viahole such that the first viahole is etched more rapidly than the second viahole.

11. The method of claim 8, wherein the simultaneously forming of the first viahole and the second viahole comprises simultaneously forming a third viahole together with the first viahole and the second viahole, the third viahole penetrating the second interlayer dielectric film, exposing the lower interconnection and having a third width greater than the first width.

12. The method of claim 8, wherein the first viahole has a first depth and the second viahole has a second depth.

13. The method of claim 8, further comprising:
forming a first etching stopper film on the first interlayer dielectric film,
the forming of the capacitor including forming the capacitor on the first etching stopper film; and
forming a second etching stopper film on the second electrode of the capacitor.

14. The method of claim 13, wherein the simultaneously forming of the first viahole and the second viahole comprises:
forming a first pre-viahole and a second viahole partially penetrating of the second interlayer dielectric film by a first etching process; and
enlarging the first pre-viahole and the second pre-viahole penetrating the second interlayer dielectric film by a second etching process, the second etching process of the first pre-viahole partially removing the dielectric film and the second etching process of the second pre-viahole partially removing the second etching stopper film.

15. The method of claim 13, wherein the simultaneously forming of the first viahole and the second viahole comprises:
forming a first pre-viahole exposing the dielectric film and a second viahole exposing the second etching stopper film by a first etching process; and
forming the first and second viaholes exposing the first and second electrodes by removing the exposed dielectric film and the exposed second etching stopper film by a second etching process, respectively.

16. The method of claim 15, wherein the first etching process is a reverse reactive ion etching (RIE) process, and the second etching process is a reactive ion etching (RIE) process.

17. The method of claim 15, wherein while the second etching process is performed, a first trench hole having a width greater than the first width is formed over the first viahole, and a second trench hole having a width greater than the second width is formed over the second viahole.
